(19) United States
(12) Patent Application Publication
(10) Pub. No.: US 2019/0131044 A1
(43) Pub. Date: May 2, 2019

(54) DIELECTRIC SUBSTRATE FOR SUPERCONDUCTIVE DEVICE AND SUPERCONDUCTIVE ARTICLE UTILIZING SUCH SUBSTRATE

(71) Applicant: TECHNOLOGY INNOVATION MOMENTUM FUND (ISRAEL) LIMITED PARTNERSHIP, Tel Aviv (IL)

(72) Inventors: Guy DEUTSCHER, Herzliya (IL); Mishael AZOULAY, Kfar-Saba (IL); Boaz ALMOG, Rehovot (IL); Amir SARAF, Yavne (IL)

(21) Appl. No.: 16/173,366

(22) Filed: Oct. 29, 2018

Related U.S. Application Data
(62) Division of application No. 15/199,103, filed on Jun. 30, 2016.
Application No. 15/199,103 is a continuation-in-part of application No. PCT/IL2015/051233, filed on Dec. 21, 2015.
(60) Provisional application No. 62/095,206, filed on Dec. 22, 2014.

(51) Int. Cl. H01F 6/06; H01L 39/24; H02H 9/02; H01F 41/04; C30B 23/02; C30B 15/34; C30B 29/22; H01L 39/16

(52) U.S. Cl. CPC H01F 6/06; H01L 39/2458; H02H 9/023; H01L 39/16; C30B 23/025; C30B 15/34; C30B 29/225; H01F 41/048

(57) ABSTRACT

A substrate structure is provided for use in a superconductive device. The substrate structure has at least one of its two opposite surfaces configured for carrying at least one superconductive structure thereon. The substrate structure comprises a substrate made of a dielectric material composition and having a tape-like shape of a predetermined geometry characterized by a width-thickness aspect ratio of at least 10 and global planarity of said at least one surface defined by a surface roughness on a nanometric scale substantially not exceeding 1 nm rms.

### TECHNOLOGICAL HELD

The present invention is in the field of superconductive devices, and relates to a dielectric substrate for use in high-temperature superconductive devices with reduced AC losses, and a superconductive device utilizing such substrate.

### BACKGROUND

One of the prominent issues today with superconducting wires is undesired AC losses. This is associated with magnetic vortices moving across the superconductor material and introducing significant losses [Ernst Helmut Brandt and Mikhail Indenbom, “Type-II-superconductor strip with current in a perpendicular magnetic field”, Phys. Rev. B Vol 48, 17 (1993) pp. 12893-12906].

Various techniques for reducing the AC losses have been developed. These include the use of non-magnetic substrates for removing ferromagnetic loss of the substrate; making the coated conductor with a filamentary design and making the filament width very narrow for reducing hysteretic losses in the superconductor layer; increasing the resistance of substrate and the interfilamentary path for reducing, respectively, eddy currents and coupling currents.

U.S. Pat. Nos. 8,481,460 and 8,227,082 describe a crystalline article including a single-crystal ceramic fiber, tape or ribbon having at least one crystallographic facet along its length, which is generally at least one meter long. In the case of sapphire, the facets are R-plane, M-plane, C-plane or A-plane facets. Epitaxial articles, including superconducting articles, can be formed on such fiber, tape or ribbon.

U.S. Pat. No. 8,664,163 describes an article including a sapphire substrate carrying a superconductive layer of a compound of the formula YBa₂Cu₃O₇₋ₓ (YBCO), the layer having surface area of at least 10 cm², and critical current of at least 100 A/cm width at a temperature of 77K. The thickness of the superconductive layer is between 10 nm and 50 nm, or may he more than 600 nm. An YSZ layer and a non-superconductive YBCO layer may separate between the superconductive layer and the substrate.

### GENERAL DESCRIPTION

There is a need in the art for a novel approach in configuring a dielectric substrate structure for use in high-temperature superconductive devices.

The inventors of the present invention have found that in the known devices of the kind specified, AC losses caused by the magnetic vortices moving across the superconductor material are associated with the planar geometry of the current generation coated conductors (i.e., thickness<<width), which causes changing high edge fields (AC fields) which in turn introduce the magnetic vortices.

For high temperature superconductors, which are promising for a wide variety of applications (such as power cables, fault current limiters, powerful electromagnets (MRI, NMR, etc.), motors and generators, etc.), in order to be of commercially value, the superconductors need to be of highest crystalline quality. Since the critical current (and hence working electric current) of known. superconductors (YBCO) is extremely sensitive to the material crystalline structure, one can only coat specific substrates that are either single crystal (e.g. sapphire, SrTiO3) or have been treated to resemble one (RABID).

There are currently two commercial options that are used as substrates: metallic (stainless-steel or Ni—W) rolling-assisted, biaxially-textured substrates (RABiTS™), and polished single crystal wafers of sapphire Al2O3), LaAl2O3, SrTiO3. Metallic tapes (aka coated conductors) are currently the only scalable solution for continuous superconducting tapes since they are available in large quantities and lengths. However, unlike single crystal substrates, metallic tapes have several disadvantages: they need special treatment to adjust orientation of grains and multiple buffer layer to compensate the disorder; they are electrically conductive, causing induced AC voltages and inevitable power loss; they have poor thermal contact with the superconducting layer (due to the structure and composition).

Single crystal sapphire substrates solve the above issues. Indeed, they are electrically insulating, have crystallographic ordered and matching the superconductor lattice size, and are in good thermal contact with the superconducting layer. However, current sapphire substrates are wafers cut from large sapphire boles (usually grown via the Kyropoulos and similar methods) which are later polished to reduce their surface roughness to allow epitaxial growth (hence, the term epipolish).

In the device configuration of the above indicated U.S. Pat. Nos. 8,481,460 and 8,227,082, the reduction of the edge fields and hence the AC losses are achieved by twisting or transposing a plurality of fibers, tapes or ribbons relative to one another along a length of the fiber, tape or ribbon. According to this technique, the fiber (tape or ribbon) has a reduced thickness-to-width ratio and is faceted, i.e. is configured with one or more crystallographic facets along the fiber's length (e.g. at least one meter long), rather than using conventional optical fibers which are round and have no facets. The faceted configuration is aimed at providing flexibility to allow twisting, braiding or transposing relative to one another along a length of the article, such as for reducing AC losses. However, entwining two opposite conducting strands together to cancel or minimize the stray fields, which technique is used with conventional copper wires, requires good insulation between the twisted wires, and also requires the wire form factor allowing the desired wire flexibility.

Another technique utilizes a bifilar straight and pancake coil configuration, where two opposite conducting planar superconducting tapes are stacked to provide two opposite current paths as close as possible in a way that will eliminate (or minimize) the stray magnetic fields [Doan N Nguyen et al., “AC loss study of antiparallel connected YBCO coated conductors”, Supercond. Sci. Technol. 22 (2009) 055014; J S\check{}ouc et al., “Coated conductor arrangement for reduced AC losses in a resistive-type superconducting fault current limiter”, Supercond. Sci. Technol. 25 (2012) 014005]. However, current generation superconducting tapes are coated on a metallic substrate, and in order to stack two such wires together without short-circuiting a good insulation is required. Adding an insulation layer that will be closely and evenly packed between the superconducting tapes and will be able to sustain multiple cooling cycles is a difficult, if not impossible, task which highly complicates the fabrication processes.

The present invention provides a substrate structure, which has a novel configuration so as to be suitable for use in a superconducting device having low AC losses, e.g. a superconductive device which has a bifilar-like configuration. The substrate structure includes a substrate made of a dielectric material composition (such as sapphire or silicon), and preferably also includes a buffer layer on at least one surface of the substrate, on which a superconductive structure is to be formed.

The substrate has a tape- or ribbon-like shape, namely is an elongated element (of a substantially rectangular cross section) having width, thickness, and length. According to the invention, the substrate has a selected, relatively high width/thickness aspect ratio enabling a long and thin configuration, and, if needed, also flexible. The width/thickness aspect ratio may be larger than 10, and preferably larger than 50. For example, the substrate may have a width higher than 5 mm and thickness less than 0.5 mm, preferably 0.15±0.05 mm thick.

In some embodiments, the substrate structure has a substantially planar configuration, i.e. substantially planar configuration of at least that surfaces on which a superconductive structure is to he formed, with high smoothness of said surface (e.g. surface roughness less than 1 nm rms, and preferably less than 0.3 nm). This configuration of the substrate structure, carrying similar superconductive structures on the opposite substantially planar surfaces thereof, allows electric current passage through the superconductive structures in opposite directions to solve the AC losses reduction problem.

In some embodiments of the invention the substrate structure is configured with a global planarity of at least one of the two opposite surfaces on which a superconductive structure is to be formed. It should be noted that, for the purposes of the present invention, such “global planarity” or “global flatness” of the surface means that the surface is substantially smooth on a nanometric scale. For example, a 1×1 micron surface has a surface roughness not exceeding 1 nm rms, and preferably less than 0.3 nm. However, on a micron scale, there may be long range thickness modulations, e.g. 10-100 micron deep (generally about tens of microns), resulting from discrete features (e.g. wavy features) arranged on a spatial millimetric scale (e.g. 100×100 micron surface). Also, local, non-ordered areas/regions or defects may exists on a limited scale, e.g. defects having a size not exceeding 3×3 μm² arranged with density not exceeding 10⁶ defects per cm².

In the double-side device configuration, the above described planar/smooth opposite surfaces of the substrate structure are configured for epitaxial growth thereon of similar, high quality superconductive structures, e.g. ReBa₂Cu₃O₇₋ₓ (‘Re’ stands for rear earth metal). Generally, as described above, the device may have a single-side configuration.

As known, high quality ReBa₂Cu₃O₇₋ₓ superconductor layer is characterized by a transition temperature of at least 86K (−185.15 C) and a critical current density at liquid nitrogen temperatures (77K) of at least 1×10⁶ A/cm². To this end, the substrate structure of the invention is also configured such that the top most layer of the substrate structure has a lattice parameter (or interatomic distance) as close as possible to that of the superconductor structure ±10% (e.g. the interatomic distance in YBa₂Cu₃O₇₋ₓ is 3.83-3.88 angstrom) to be formed on said layer. Such layer is a buffer layer on the planar surface of the substrate which also prevents atom diffusion between the dielectric substrate and the superconducting layer.

Thus, the substrate structure of the invention can be coated on one or both sides thereof (i.e. planar smooth surface(s)) with suitable superconducting layers, e.g. ReBa₂Cu₃O₇₋ₓ superconducting layers, and can be used in an AC superconducting device with a bifilar winding of the superconductor. The dielectric nature of the substrate allows driving electric currents in opposite directions on both sides (anti-parallel configuration) which reduces the stray magnetic fields from the two faces, thus substantially lowering the AC losses.

In some embodiments, the buffer layer on one or both smooth parallel surfaces of the substrate is a continuous layer (unpatterned), and preferably has the surface roughness smaller than 1 nm rms.

The thickness of the buffer layer may be in a range of 10-100 nm, or in a range of 100-1000 nm.

The buffer layer may include yttrium stabilized zirconia (8-10%), aka YSZ, or cerium dioxide (CeO₂). The buffer layer may he comprised of two or more compounds other than the material composition of the substrate.

The dielectric substrate may be a single crystal sapphire ribbon/tape having r-plane orientation of the planar/smooth parallel surfaces, or a single crystal silicon ribbon/tape having [100] orientation of the planar parallel surfaces.

Thus, the present invention, in its one aspect, provides a substrate structure for use in a superconductive device, the substrate structure having at least one of its two opposite surfaces configured for carrying thereon a superconductive structure, wherein the substrate structure comprises a substrate made of a dielectric material composition and having a tape-like shape of a predetermined geometry characterized by a width-thickness aspect ratio of at least 10 and substantial planarity of said at least one of the opposite surfaces defined by a surface roughness substantially not exceeding 1 nm rms.

The substantial planarity of said at least one surface may be characterized by global planarity defined by said surface roughness on a nanometric scale substantially not exceeding 1 nm rms, while allowing local thickness modulation on a micron scale.

As indicated above, the substrate may further comprise at least one buffer layer on the at least one surface of the substrate configured for carrying the superconductive structure. The buffer layer is selected to have a lattice parameter matching a lattice parameter of the superconductor structure to be carried thereon. The buffer layer is at least 100 times thinner than the substrate. Such a thin dielectric substrate (as well as the substrate-and-buffer structure) provides for desired flexibility of the substrate structure. For example, a bending radius of such flexible structure substantially not exceeds 20 cm. The substrate structure may be as long as desired, e.g. longer than 1 m.

The substrate is preferably made of sapphire or silicon material.

It should be understood that such a thin substrate structure (i.e. with a high width-thickness aspect ratio of at least 10, e.g. substrate structure of less than 0.5 mm thickness) provides for placing two superconductive structures very close to one another.

In some embodiments, the two superconductive structures may be located on the opposite surfaces of the substrates structure and are thus separated solely by the substrate structure between them. This is a double-sided configuration of a superconductive element. In some other embodiments, where the superconductive element is a single-side element (i.e. the superconductive structure is located on one side of the substrate structure), two such elements may be accommodated parallel to one another and close to one another, up to a physical contact between them where the surface of the substrate structure of one element faces (contacts) the superconductive structure of the other element. In some embodiments, such close adjacent superconductive elements (single- or double-sided elements) may be adjacent segments of the windings of a coil formed by a long and flexible superconductive element/tape.

According to another broad aspect of the present invention, it provides a superconductive device comprising at least one superconductive element, the superconductive element comprising the above-described substrate structure and a superconductive structure on one of the opposite surfaces, or two similar superconductive structures on both opposite planar surfaces (global planarity) of the substrate structure. The device allows electric current passage in opposite directions through the superconductive structures, being thereby characterized by reduced AC losses.

In such device, the substrate structure with the at least one superconductive structure on the at least one of its planar surfaces may be configured to form at least one bifilar superconducting coil. When electric current flows through the coil, electric current in segments of adjacent coil windings facing each other are identical in magnitude and have opposite directions, thereby reducing stray magnetic fields and providing reduced AC losses.

The device may include at least two spaced apart superconductive elements, each superconductive element being formed by the substrate structure with the two superconductive structures on the two opposite planar surfaces (e.g. global-planarity) of the substrate structure. The superconductive elements may be connected in series or in parallel. If electric current flows through the superconductor element, electric current flowing in one of the superconductive structures is identical in magnitude and opposite in direction to electric current flowing in the other superconductive structure, thereby reducing stray magnetic fields and providing reduced. AC losses.

According to yet another broad aspect of the invention, there is provided a bifilar-type superconductive device comprising at least one bifilar superconductive coil, the superconductive coil being formed by thin and flexible substrate structure of a tape-like shape carrying at least one superconductive tape on at least one of its opposite surfaces, the substrate structure comprising a substrate, which is made of a dielectric material composition and which has a predetermined geometry characterized by a width-thickness aspect ratio of at least 10 and global planarity of said opposite surfaces defined by a surface roughness on a nanometric scale substantially not exceeding 1 nm rms, such that when electric current flows through the coil, the electric current in segments of adjacent coil windings facing each other are identical in magnitude and have opposite directions, thereby reducing stray magnetic fields and providing reduced to AC losses of the device.

According to yet further broad aspect of the invention, there is provided a bifilar-type superconductive device comprising at least two spaced apart superconductive elements, each superconductive element being formed by a thin and flexible substrate structure having a tape-like shape and carrying two superconductive tapes on its two opposite surfaces, the substrate structure comprising a substrate which is made of a dielectric material composition and has a predetermined geometry characterized by a width-thickness aspect ratio of at least 10 and global planarity of the opposite surfaces defined by a surface roughness which on a nanometric scale substantially does not exceed lnm rms, such that when electric current flows through the superconductor element, the electric current in one of the superconductive structures is identical in magnitude and opposite in direction to electric current in the other superconductive structure of said element, thereby reducing stray magnetic fields and providing reduced AC losses.

The inventors have also developed a superconducting device based on single or double side coated as-grown, continuously long, sapphire ribbon that can be produced by known pulling techniques, such as the Edge-defined Film-fed Growth (EFG) technique. The as-grown sapphire strips possess properties providing several benefits over both existing epi-polished sapphire substrates and coated conductors. This approach eliminates a need for polishing or surface treatment (such as RABiTS), and thus provides for much easier and cost effective manufacturing process, as well as flexibility in geometry and size of the strip. A continuously long tape can be manufactured (due to the EFG method). The lateral size of the strip is not limited, and in principle a feeding system can allow kilometers long strips. The tapes may be very thin. Achieving thin (˜0.15 mm thickness) tapes is much easier with as-grown strips. The polishing of thin (less than 0.3 mm) and possible large size sapphire is exponentially difficult. Using thin tapes is beneficial because they are flexible and are characterized by low AC losses. Using the dielectric nature of sapphire having an antiparallel current to configuration reduces AC losses substantially in thin tapes. Also, pulling as-grown strip by methods such as EFG provides the ability to pull multiple strips simultaneously thus providing high throughput of the manufacturing process.

Thus, the invention, in it yet further aspect, provides a method for manufacturing a superconductive device. The method comprises: applying an is Edge Defined Growth to a ribbon made of a dielectric material composition, thereby pulling the ribbon directly to a desired tape-like shape characterized by a width-thickness aspect ratio of at least 10 and substantial planarity of at least one of two opposite surfaces of the ribbon tape defined by a surface roughness on nanometric scale substantially not exceeding 1 nm rms; and forming at least one superconductor layer above said at least one surface of the substrate structure (either directly on the substrate or using at least one buffer layer coating).

### BRIEF DESCRIPTION OF THE DRAWINGS

The patent or application file contains at least one drawing executed in color. Copies of this patent or patent application publication with color drawings will be provided by the Office upon request and payment of the necessary fee.

In order to better understand the subject matter that is disclosed herein and to exemplify how it may be carried out in practice, embodiments will now be described, by way of non-limiting example only, with reference to the accompanying drawings, in which:

FIGS. 1A and 1B schematically illustrate the substrate structure according to the examples of the invention;

FIGS. 1C to 1F illustrate experimental substrate structure showing global planarity (nanometric scale roughness) and thickness modulation (millimetric scale wavy features) of the surface of the substrate obtained using the technique of the invention;

FIG. 2 schematically illustrate an example of manufacturing a double-side coated substrate; and

FIGS. 34 and 3B schematically illustrate two examples of a superconductive device utilizing the substrate structure of the invention.

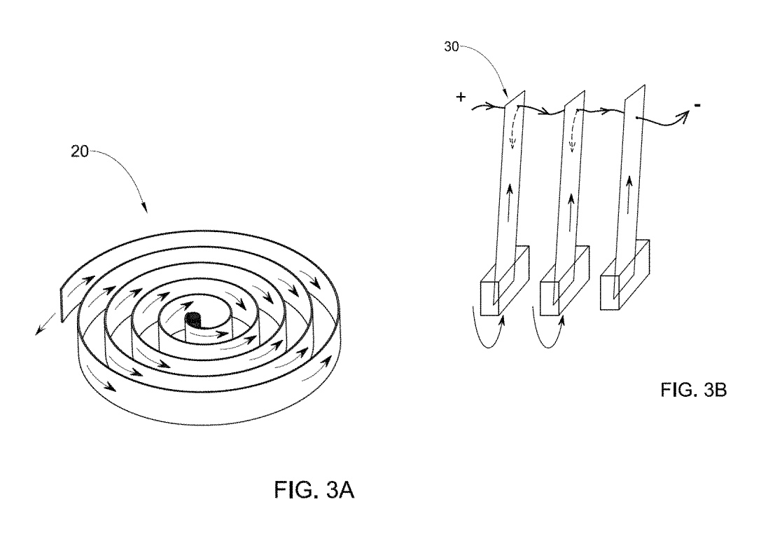

### DETAILED DESCRIPTION OF EMBODIMENTS

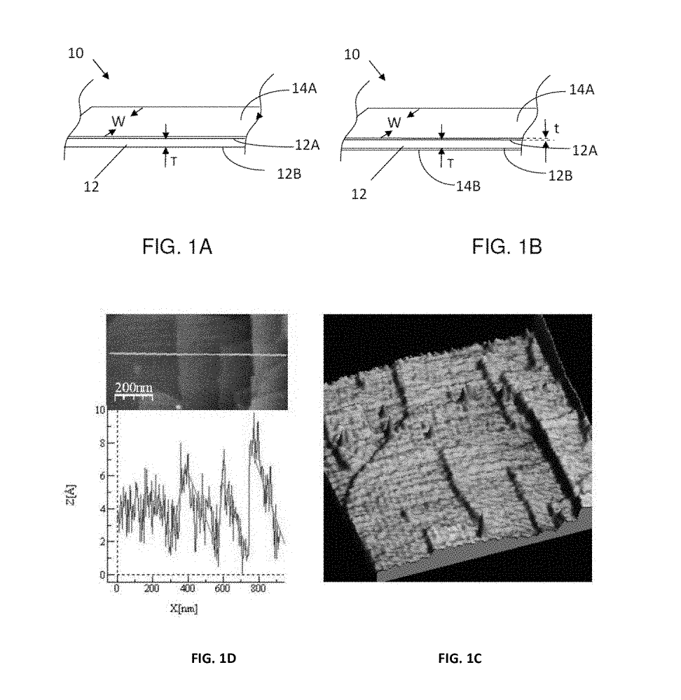

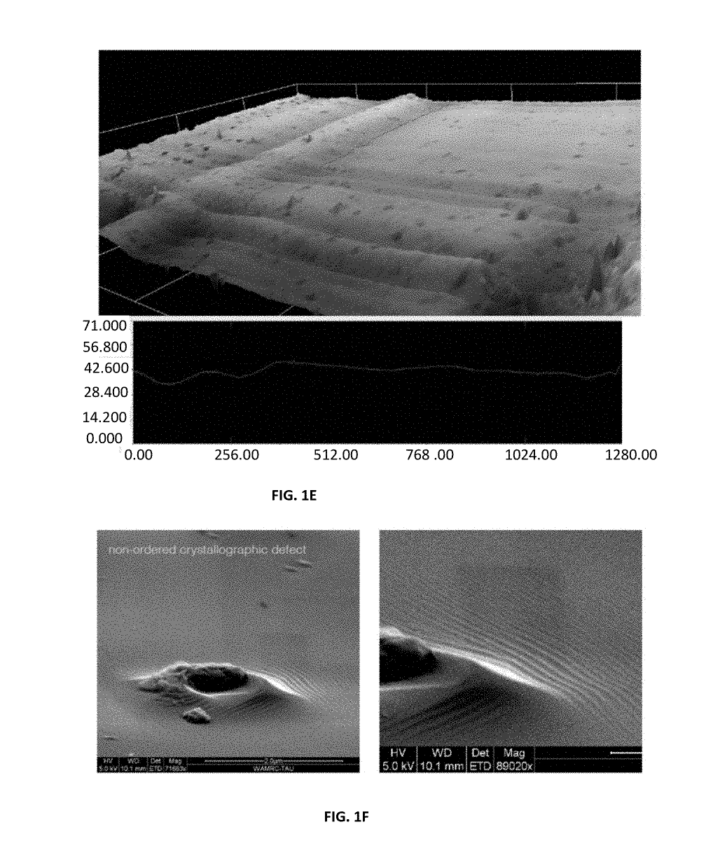

Reference is made to FIGS. 1A and 1B showing schematically two examples of the substrate structure 10 of the invention. The substrate structure includes a dielectric substrate 12 of a predetermined geometry, as will be exemplified further below. Also, preferably, the substrate structure includes at least one buffer layer on at least one surface of the substrate. In the example of FIG. 14, the substrate structure 10 includes the buffer layer 144 on one surface 12A of the substrate 12. In the example of FIG. 1B, the substrate structure 10 includes two buffer layers 144 and 14B on two opposite surfaces 124 and 12B, respectively, of the substrate 12.

The geometry of the substrate 12 is selected to provide a high aspect ratio between the width W and thickness T of the substrate. The thickness t of the buffer layer 14A (14B) is at least two orders smaller than thickness T of the substrate 12. For example, the substrate may have thickness T about 100 μm and may be coated (on at least one surface) by the buffer layer having thickness t about 1 μm or less. Hence, the thickness of the substrate structure 10 is practically defined by the thickness T of the substrate 12. It should be understood that the illustration is schematic, and the geometric parameters are not in scale.

The thickness of the substrate structure is preferably in a range of 0.05-0.4 mm. In some embodiments, the length of such high aspect ratio substrate structure is such that the substrate structure is flexible with a bending radius of 20 cm or less. The width of the substrate structure is preferably in a range of 4-10 mm, but in some embodiments the width may be larger than 10 nm. The width-thickness ratio may be in a range of about 10-50, and in some embodiments may be larger than 50.

Generally, the width of the substrate structure is at least 10 times higher than the thickness thereof. Such a thin substrate structure may be desirably flexible, e.g. with a bending radius of less than 20 cm, allowing it to be compactly packed to form a device with a moderate form factor. The length of the substrate structure may be in a range of 0.1 m to 10 m, or larger than 10 m.

Also, the substrate 12 has a substantially planar geometry, i.e. has global planarity or flatness of at least that surface of the substrate on which the buffer layer is to be formed to carry a superconductor structure on top thereof. In case of the double-side configuration of a superconducting device, the substrate 12 has two opposite planar surfaces 12A and 12B which are substantially parallel to one another.

As indicated above, the global planarity/flatness of the substrate's surface may be defined by its substantial/global smoothness on a nanometric scale. For example, a 1×1 micron surface has surface roughness substantially not exceeding 1 nm rms, and preferably less than 0.3 nm rms. As for the millimetric scale (e.g. 100×100 micron surface), the surface may have micron-scale thickness modulations, e.g. 10-100 micron deep formed by wavy features on spatial millimeter scale, as well as local non-ordered (random or quazi-random) regions or defects. Such regions/defects are of a small size (e.g. not exceeding 3×3_{μm}²) arranged with low density, e.g. not exceeding 10⁶ defects per cm².

In this connection, reference is made to FIGS. 1C to 1F showing the experimental substrate's surface. FIG. 1C shows an atomic force microscope (AFM) image of 1×1 micron area of the flat substrate's surface, and FIG. 1D shows the surface roughness along an arbitrary line exhibiting steps with a smooth roughness of less than 1 nm. FIG. 1E a long range (millimetric scale) thickness modulation of such fiat substrate. FIG. 1F illustrates non-ordered local crystallographic defects on the flat surface. In this example, the substrate was produced using direct pulling technique (Edge Defined Growth (EEG)), providing for pulling ribbon directly in its desired shape.

The above-described high aspect ratio, global planarity, dielectric substrate can be produced directly in the desired shape and surface quality using appropriate techniques such as Edge Defined Growth (EFG). Pulling ribbon directly in its desired shape, instead of commonly used bulk-crystal growth techniques, has several key advantages, as follows. This “direct pulling” technique eliminates a need for post growth polishing and cutting. The substrate is directly made in the desired shape and geometry. Desirably small surface roughness of the as-grown substrate can he automatically achieved (the so-obtained surface is flat/smooth), e.g. roughness smaller than 1 nm rms. In comparison, when using bulk growth methods, the dielectric material is cut from a large crystal boule and then undergoes several complicated polishing steps. Also the “direct pulling” technique provides shorter production time, which is due to the small mass of the thin substrate (short cooling times). Also, this technique provides for production of a continuous substrate without length limitation.

The “direct pulling” based manufacturing method, such as the EFG method, may be used for manufacturing a continuously long single crystal thin r-plane sapphire ribbon or tape. Typically, the tape is less than 1 mm thick and usually more than 0.1 mm thick, and possess some flexibility.

As an example, the inventors tested a 0.15 mm thick sapphire tape with a bending radius of 12.5 cm. For some applications, e.g. current leads, the sapphire strips may be shorter, about 1 m long, thicker than about 0.3 mm thick, and consequently nonflexible.

Another exemplary application is a fault current limiter (FCL) which contains multiple (e.g. 50-100×) 1 m long non-flexible sapphire strips, having 0.5 mm thickness and 10 cm width. In the final device, these long strips may be connected in parallel/series.

Yet another application is power cables that are continuously long and flexible and exhibit low AC losses. Such power cables will require long (>1 km), thin (−0.15 mm thick) sapphire strips that are flexible (e.g. having a bending radius of ˜15cm).

As indicated above, the tape width is substantially larger than the thickness, preferably having a width/thickness aspect ratio of more than 10 and having two extending (or major) surfaces. The surfaces have global planarity as described above with the inherit waviness (local pattern or thickness modulations). Preferably, the sapphire tape width is about 4-12 mm. The two major surfaces of the tape have an r-plane crystallographic orientation (1-102) possibly with a small mis-cut angle of less than 5 degrees.

The manufacturing of a long planar sapphire tape is done by pulling a seed from an appropriate pedestal/crucible setup. Such pulling method is inevitably prone to vibrations that cause thickness variations along the strip (wavy features). Moreover, chemical contamination from the pulling system (crucible, pedestal, etc.) and surrounding materials can locally damage the crystallographic order of the strip. The sapphire strip produced by such technique possesses physical properties allowing it to be successfully coated with a high quality epitaxial superconductor layer (e.g. YBCO) by various, well known, techniques. As indicated above, the as-grown sapphire tape is characterized by global planarity on a nano-metric scale (e.g. scanning a surface of 1×1 micron) defined by the surface roughness substantially not exceeding lnm rms. Usually, the surface consists of multiple step like features, each step being nanometrically flat (<1 nm rms) and the height of wavy features (thickness modulation) being less than 10 nm. On a mm-scale (e.g. 100×100 micron surface) there may be long range thickness modulations 10-100 μm deep. Local, non-ordered areas or defects (not exceeding 3×3 μm² size) may exists on a limited scale with overall spatial density not exceed 10⁶ defects per cm².

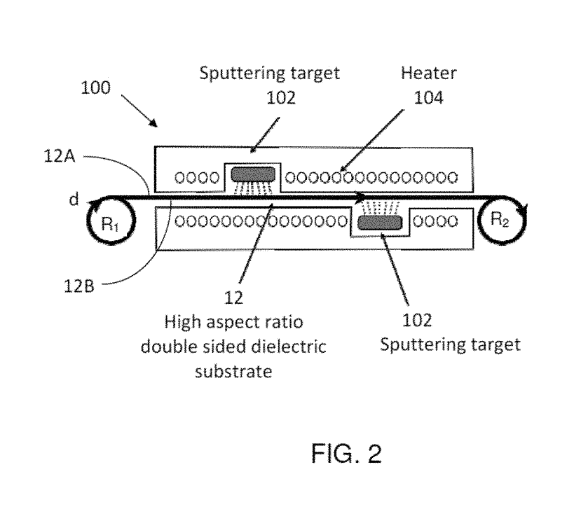

Reference is made to FIG. 2 schematically showing an example of a system 100 for producing double-side coated substrate structure 10 (such as that of FIG. 1B). In this example, the system utilizes the magnetron sputtering technique. As shown, after producing the above-described dielectric substrate 12 (i.e. with the desired geometry: high aspect ratio and high planarity), the substrate 12 is coated on both surface 12A and 12B thereof with an appropriate buffer layer. In the present example, the system 100 includes magnetic sputters 102 and heaters 104 accommodated at opposite sides of the thin substrate tape being rolled in a rolling direction d between two support rollers R₁ and R₂. Generally, the buffer layer can be epitaxially grown using any known suitable method, such as Magnetron sputtering, Pulsed Laser Deposition (PLD), Sol-Gel deposition, Ion-beam-assisted deposition (IBAD), etc. The coating can be done continuously using a feeding mechanism (e.g. rolling mechanism as shown in the figure) on both sides simultaneously. Alternatively, the buffer can be coated on one or both surfaces 12A, 12B, separately, possibly ex-situ.

It should be noted, although not specifically shown, that at least one superconductor layer may then be formed on the substrate structure 10. The superconductive layer may be YBa₂Cu₃O^{7-x}. The superconductive structure (single- or multi-layer structure) may be formed directly on top of the buffer layer. Alternatively, an additional self-template layer may be provided between so the buffer and the superconductor.

Thus, the present invention provides a novel substrate structure for use in a superconducting device, enabling low AC losses in the device based on the high aspect ratio double sided substrate. The superconducting device of the invention includes a superconducting tape utilizing the above-described substrate structure. More specifically, such a device may include at least one superconductor tape (generally, thin superconductive structure) coated on the at least one surface of the aforementioned high aspect ratio high planarity dielectric substrate structure.

In some embodiments, the device is configured for driving AC currents in opposite directions in the two superconducting structures. This significantly reduces the electric AC losses as compared to a similar device made from metallic coated superconductor tapes (coated conductor).

A flexible double-sided superconductor tape structure with the properties described above may be wound in a coil shape, forming what is known as a is bifilar winding coil. Such a bifilar coil has a low parasitic self-inductance, while maintaining a small form factor with a large amount of superconducting material.

Such a device may be configured and operable as a superconducting fault current limiter or SFCL, a reusable fuse that limits the current in a power grid. An SFCL is connected in series to the power grid, and, during ideal operation, does not dissipate energy (no voltage drop). During a fault, the superconductor inside becomes a normal material and dissipates the excess energy in the form of heat. The total power capacity of an SFCL depends on the total area of the superconducting material, with typical energy densities of 1000-2000 W/cm².

Reference is made to FIGS. 3A and 3B exemplifying the bifilar-type superconductive devices utilizing the high aspect ratio, global planarity dielectric substrate structure. In the example of FIG. 3A, the superconducting device 20 contains a bifilar superconducting coil (generally, at least one such coil) made of the above described flexible high-aspect ratio dielectric substrate structure. In the example of FIG. 3B, the superconducting device 30 is constructed of multiple separated pieces of the aforementioned non-flexible double sided superconducting tape. Superconductor tapes can be connected in series (forming device elements) to achieve higher power limiting capabilities through having an effectively larger superconductor area and hence higher normal state resistance. In addition, multiple device elements can be connected in parallel to achieve higher current capacity of the entire superconducting device. The electric current in each superconductor element flows in a so-called “anti-parallel fashion”, i.e. the current on the top layer is identical in magnitude but opposite in direction to the current flowing in the bottom layer, as shown in FIG. 3B, in order to reduce stray magnetic fields and achieve low AC losses.

As described above, the substrate used in such bifilar coil may be made from any known suitable dielectric material composition. The use of the dielectric substrate structure made from sapphire or silicon might be advantageous. For example, this enables to obtain higher energy capacity, as compared to an FCL based on coated conductors. This is due to better heat conduction of the substrate. The high thermal conductance assures that, during a fault, heat propagates quickly along the superconductor thereby avoiding high energy concentration and possible burn out of the device. It has been shown that sapphire wafers provide for increased, up to 3 orders of magnitude, power limiting capabilities [Ernst Helmut Brandt and Mikhail Indenbom, “Type-II-superconductor strip with current in a perpendicular magnetic field”, Physical Review B, Volume 48, Number 17, 1 Nov. 1993, pp. 12893-12906]. Also, the use of sapphire or silicon substrate reduces the maintenance and cryogenic costs. The bifilar configuration, enabled by the dielectric thin substrate, reduces the stray magnetic fields and substantially lowers the AC losses during ideal operation.

What is claimed is:

1. A superconductive device comprising at least one superconductive unit, the superconductive unit comprising a substrate structure, and at least one superconductive structure on at least one surface of the substrate structure, wherein
the substrate structure comprises a substrate made of a dielectric material composition and having a tape-like shape of a predetermined geometry characterized by a width-thickness aspect ratio of at least 10,
at least one surface of the substrate facing said at least one superconductive structure has a first global surface pattern of wavy features arranged with relatively low density on a spatial millimetric scale, and a second local surface pattern defined by a surface roughness on a nanometric scale substantially not exceeding 1 nm rms.

2. The superconductive device of claim 1, wherein said wavy features are of tens of microns depth.

3. The superconductive device of claim 1, wherein said substrate structure further comprises at least one buffer layer on said at least one surface of the substrate, the superconductive structure being located on a surface of the buffer layer.

4. The superconductive device of claim 3, wherein said at least one buffer layer is configured to have a lattice parameter matching a lattice parameter of the superconductor structure on top thereof.

5. The superconductive device of claim 4, wherein the buffer layer is at least 100 times thinner than the substrate.

6. The superconductive device of claim 1, wherein the substrate has a thickness substantially not exceeding 0.5 mm.

7. The superconductive device of claim 1, wherein the substrate is made of sapphire or silicon material.

8. The superconductive device of claim 1, wherein said substrate structure is longer than 1 m.

9. The superconductive device of claim 1, wherein the substrate structure is flexible, having a bending radius substantially not exceeding 20 cm, thereby providing flexibility of the at least one superconductive unit on said at least one surface.

10. The superconductive device of claim 1, wherein said at least one surface having the global and local patters further comprises an arrangement of discrete features of a size not exceeding 3×3 μm² arranged with density not exceeding 10⁶ features per cm².

11. The superconductive device of claim 1, wherein the superconductive unit further comprises an additional similar superconductive structure on an opposite surface of the substrate structure, respectively.

12. The superconductive device of claim 10, wherein the superconductive unit comprising the substrate structure with the at least one superconductive structure on the at least one surface, is configured to form at least one bifilar superconducting coil, such that electric current flowing in segments of adjacent coil windings facing each other are identical in magnitude and have opposite directions, said superconductive device being thereby configured and operable as a bifilar-type superconductive device reducing stray magnetic fields and providing reduced AC losses.

13. A fault current limiter device comprising the superconductive device of claim 12.

14. The superconductive device of claim 10, comprising at least one additional similar superconductive unit, at least two superconductive units being arranged in a spaced-apart parallel relationship.

15. The superconductive device of claim 14, wherein said at least two superconductive units are connected in series or in parallel.

16. The superconductive device of claim 15, wherein in each of said at least two superconductor units, electric current flowing in one of the superconductive structures is identical in magnitude and opposite in direction to electric current flowing in the other superconductive structure, thereby reducing stray magnetic fields and providing reduced AC losses.

17. The superconductive device of claim 1, being configured and operable as a fault current limiter.

18. The superconductive device of claim 1, manufactured by a method comprising:
(i) preparing the substrate by applying an Edge Defined Growth to a ribbon made of a dielectric material composition, thereby pulling the ribbon directly to a desired tape-like shape characterized by the width-thickness aspect ratio of at least 10 and having, on at least one surface of the tape-like substrate, the first global surface pattern of wavy features arranged with relatively low density on a spatial millimetric scale and the second local surface pattern defined by a surface roughness on a nanometric scale substantially not exceeding 1 nm rms;
(ii) forming at least one superconductive structure above said at least one surface of the substrate.

19. The superconductive device of claim 18, wherein said method further comprises, prior to step (ii), forming a buffer layer on said at least one surface of the substrate, the buffer layer having a lattice parameter matching a lattice parameter of the superconductor structure.

20. The superconductive device of claim 19, wherein the buffer layer is at least 100 times thinner than the ribbon tape.

21. The superconductive device of claim 18, wherein the ribbon tape has a thickness substantially not exceeding 0.5 mm.

22. The superconductive device of claim 18, wherein the substrate is made of sapphire or silicon material.

23. The superconductive device of claim 18, wherein the substrate is flexible, having a bending radius substantially not exceeding 20 cm.

24. The superconductive device of claim 19, wherein the buffer layer is formed on the substrate using epitaxial growth.

25. The superconductive device of claim 24, wherein said epitaxial growth comprises at least one of the following: Magnetron sputtering, Pulsed Laser Deposition (PLD), Sol-Gel deposition, Ion-beam-assisted deposition (IBAD).
